(19) United States
(12) Patent Application Publication
(10) Pub. No.: US 2022/0415853 A1
(43) Pub. Date: Dec. 29, 2022

(54) HEAT INSULATING INTERCONNECT FEATURES IN A COMPONENT OF A COMPOSITE IC DEVICE STRUCTURE

(71) Applicant: Intel Corporation, Santa Clara, CA (US)

(72) Inventors: Aleksandar Aleksov, Chandler, AZ (US); Johanna Swan, Scottsdale, AZ (US); Shawna Liff, Scottsdale, AZ (US); Feras Eid, Chandler, AZ (US); Adel Elsherbini, Tempe, AZ (US); Julien Sebot, Portland, OR (US)

(73) Assignee: Intel Corporation, Santa Clara, CA (US)

(21) Appl. No.: 17/358,948

(22) Filed: Jun. 25, 2021

(51) Int. Cl. H01L 25/065; H01L 25/18; H01L 23/00; H01L 25/00

(52) U.S. Cl. CPC H01L 25/0657; H01L 25/18; H01L 24/05; H01L 24/06; H01L 24/08; H01L 24/80; H01L 25/50; H01L 2225/06589; H01L 2224/05686; H01L 2224/0569; H01L 2224/05647; H01L 2224/05613; H01L 2224/05617; H01L 2224/05649; H01L 2224/05609; H01L 2224/05611; H01L 2224/05618; H01L 2224/05605; H01L 2224/05573; H01L 2224/05655; H01L 2224/06519; H01L 2224/08145; H01L 2224/80895; H01L 2224/80896; H01L 2924/0542; H01L 2924/0543; H01L 2924/0544; H01L 2924/3656; H01L 2924/1431; H01L 2924/1434; H01L 2924/01029; H01L 2924/01083; H01L 2924/01052; H01L 2924/01025; H01L 2924/01049; H01L 2924/0105; H01L 2924/0103; H01L 2924/01031; H01L 2924/01028; H01L 2924/067; H01L 2924/0705

(57) ABSTRACT

A composite integrated circuit (IC) structure includes at least a first IC die in a stack with a second IC die. Each die has a device layer and metallization layers interconnected to transistors of the device layer and terminating at features. First features of the first IC die are primarily of a first composition with a first microstructure. Second features of the second IC die are primarily of a second composition or a second microstructure. A first one of the second features is in direct contact with one of the first features. The second composition has a thermal conductivity at least an order of magnitude lower than that of the first composition and first microstructure. The first composition may have a thermal conductivity at least 40 times that of the second composition or second microstructure.

### BACKGROUND

The microelectronic industry is continually striving to produce higher computational performance in smaller microelectronic packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dies that are integrated into one functional unit. These composite, or heterogeneous, integrated circuit (IC) device structures may include tiles, chips, chiplets, or dies created using diverse technologies and materials. The tiles, chips, chiplets, or dies may be stacked vertically, placed horizontally, or both. Connections between different devices may employ a variety of technologies, including hybrid bonding.

Composite IC device structures can pose many thermal challenges. As one example, when devices like tiles, chips, chiplets, or dies are stacked vertically, a portion of a device generating a significant amount of heat may be placed near a portion of another device that is thermally sensitive. In this situation, heat from one device can be detrimental to operation of thermally sensitive circuitry or logic of the other device. While dielectric materials typically used in packaging and hybrid bonding are thermally insulating, the heat transfer these materials provide may be insufficient to avoid hot spots during the operation of thermally sensitive circuitry or logic.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels are repeated among the figures to indicate corresponding or analogous elements. In the figures:

FIGS. 1A and 1B respectively illustrate cross-sectional views of a composite IC device structure comprising a plurality of components and a portion of the composite IC structure, in accordance with some embodiments;

FIGS. 2A and 2B illustrate cross-sectional views of heat insulating interconnect features of a component of a composite IC structure, in accordance with some embodiments;

FIGS. 3A and 3B illustrate cross-sectional views of portions of a composite IC device structure comprising a plurality of components, in accordance with some embodiments;

FIGS. 4A, 4B, 4C, and 4D illustrate cross-sectional views of heat insulating interconnect features of a component of a composite IC device structure during a fabrication process, in accordance with some embodiments;

FIGS. 5A, 5B, 5C, 5D, and 5E illustrate cross-sectional views of heat insulating interconnect features of a component of a composite IC device during a fabrication process, in accordance with some embodiments;

FIG. 6 is flow diagram of a method for assembling a composite IC structure having a component that includes at least one heat insulating interconnect feature, in accordance with some embodiments.

FIG. 7 is a functional block diagram of an electronic computing device employing a composite IC device structure comprising one or more components having heat insulating interconnect features, in accordance with some embodiments; and

FIG. 8 illustrates a mobile computing platform and a data server machine employing a composite IC device structure comprising one or more components having heat insulating interconnect features, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with each of the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The term “BEOL” generally refers to wafer-level monolithic fabrication operations performed after the formation of the active and passive devices within a device layer during front-end of-line (FEOL) processing. BEOL processing generally entails a series of operations where metal features (metallization) are defined within dielectric material layers to route connections between active devices. BEOL processing generally has feature pitches much smaller than a feature pitch of interconnects that couple an IC chip to some host component (e.g., interposer or package substrate).

When semiconductor devices are stacked in a composite, or heterogeneous, IC chip, thermal cross talk from one device can be detrimental to the operation of thermally sensitive circuitry or logic of an adjacent device. While dielectric materials typically used in packaging and hybrid bonding are thermally insulating, these dielectric materials may not provide adequate insulation in conjunction with the significant thermal conductivity provided by interconnects and bond pads, typically of copper. This may be of particular concern at hybrid bonding interfaces where a significant portion of the surface area is metallization. In accordance with some embodiments, interconnects and bond pads made from electrically conductive, yet thermally insulating materials are provided to improve thermal decoupling of components in a heterogeneously integrated computational system.

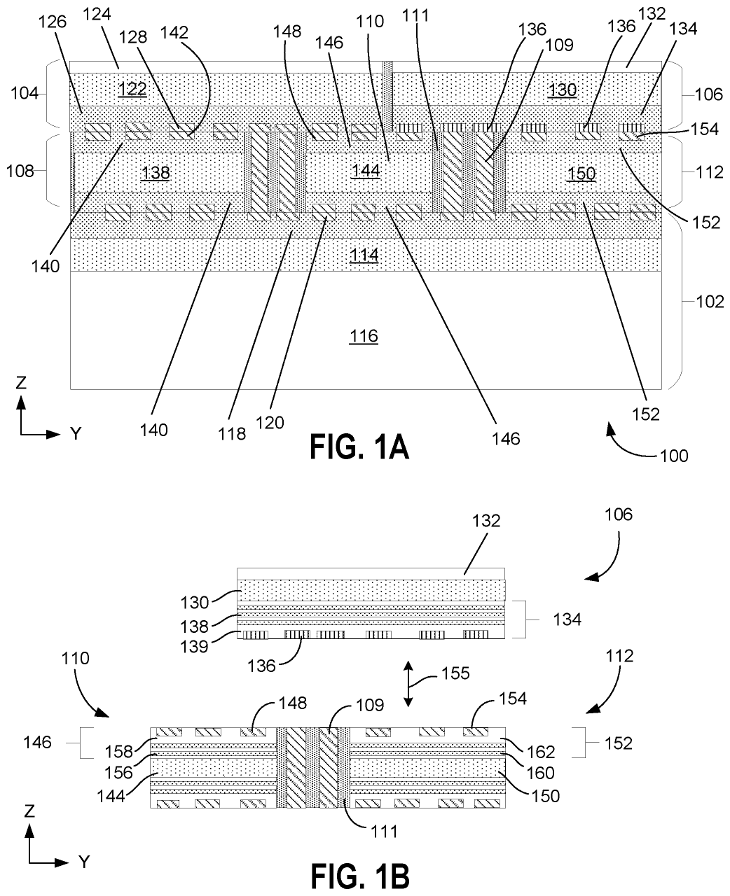

FIG. 1A is a cross-sectional illustration of a composite, or heterogeneous, IC device structure 100 comprising a plurality of components according to some embodiments. IC device structure 100 comprises microelectronic components 102, 104, 106, 108, 110, and 112. In various embodiments, each individual component 102, 104, 106, 108, 110, and 112 may be any of a tile, chip, chiplet, or die. In addition, any combination of: tile, chip, chiplet, or die components may be included in IC device structure 100. As one example, component 102 may be a chip, component 104 may be a chiplet, component 106 may be a tile, and component 108 may be a die. IC device structure 100 also includes one or more interconnect pillars or through-mold-vias (TMVs) 109 encapsulated using molding compound 111.

A “chiplet” or “micro-chiplet” is a singulated die that has a smaller footprint than that of the host IC chip with which it is packaged and lacks the full function circuitry of a stand-alone IC die. For example, a first chiplet may include only a CPU core, but lack a voltage regulation (VR) system for powering the core or I/O circuitry for communicating off the IC device structure 100 while a second chiplet may include the VR or the I/O circuitry but lack core circuitry, etc. Functionally, within a composite IC chip one or more chiplets may supplement the function of a host IC chip. A chiplet may, for example, be any of a wireless radio circuit, microprocessor circuit, electronic memory circuit, floating point gate array (FPGA), power management and/or power supply circuitry, or include a MEMS device. In some other examples, a chiplet includes banks of active repeater circuitry to improve host IC interconnects (e.g., network-on-chip architectures). A repeater chiplet may, for example, include a repeater bank supporting 2000+ signals within a chiplet area of 0.4 mm² (at 10 μm) bonded interconnect pitch. In other examples, a chiplet may include clock generator circuitry or temperature sensing circuitry. In other examples, a chiplet may include one or more electrostatic discharge (ESD) protection circuitry banks in-line with first-level interconnects of the composite chip structure. In still other examples, the chiplet includes a second level of logic circuitry that, along with the host IC, implements 3D circuitry (e.g., mesh network-on-chip architectures).

The composite microelectronic IC device structures described herein may be manufactured with a hybrid of monolithic and die-level bonding techniques to form one or more of the features or attributes provided in accordance with various embodiments. The chiplet(s) may be partially or fully fabricated in a monolithic process separate from that of a host chip. As such, the chiplet(s) may utilize the same or different semiconductor device technologies as the host chip. An IC chiplet may be attached to the host IC chip at any suitable metallization “layer” or “level” prior to a final metallization layer that is to interface with first level interconnects (FLI) of the composite chip device. Partially or completely fabricated chiplets may be singulated from a wafer, and placed on a host die wafer, for example by a pick-and-place operation at a particular stage of host wafer BEOL metallization. Chiplet attach may comprise a metal feature bonding or metal feature and dielectric (hybrid) bonding. The feature pitch at the chiplet-to-host interface metallization may absorb chiplet-host alignment imprecision.

Referring again to FIG. 1A, component 102 of IC device structure 100 includes at least one device layer 114 that is between substrate 116, and one or more BEOL metallization layers 118 that have been monolithically fabricated over device layer 114. At least one of metallization layers 118 of component 102 includes conductive features 120. In some embodiments, component 102 is a host IC chip. Component 102 may include one or more through-glass vias (TGVs) or one or more through-substrate vias (TSVs) (not shown in FIG. 1A).

Component 104 of IC device structure 100 includes at least one device layer 122 that is between substrate 124, and one or more BEOL metallization layers 126 that have been monolithically fabricated over device layer 122. At least one of metallization layers 126 of component 104 includes conductive features 128. Component 104 may include one or more TGVs or one or more TSVs (not shown in FIG. 1A).

Component 106 of IC device structure 100 includes at least one device layer 130 that is between substrate 132, and one or more BEOL metallization layers 134 that have been monolithically fabricated over device layer 132. In some embodiments, at least one of metallization layers 134 of component 106 includes conductive features 136. Component 106 may include one or more TGVs or one or more TSVs (not shown in FIG. 1A).

Component 108 of IC device structure 100 includes at least one device layer 138 and one or more BEOL metallization layers 140 that have been monolithically fabricated over device layer 138. At least one of metallization layers 140 of component 108 includes conductive features 142. Component 108 may include one or more TGVs or one or more TSVs (not shown in FIG. 1A).

Component 110 of IC device structure 100 includes at least one device layer 144 and one or more BEOL metallization layers 146 that have been monolithically fabricated over device layer 144. At least one of metallization layers 146 of component 110 includes conductive features 148. Component 110 may include one or more TGVs or one or more TSVs (not shown in FIG. 1A).

Component 112 of IC device structure 100 includes at least one device layer 150 and one or more BEOL metallization layers 152 that have been monolithically fabricated over device layer 150. At least one of metallization layers 152 of component 112 includes conductive features 154. Component 112 may include one or more TGVs or one or more TSVs (not shown in FIG. 1A).

FIG. 1B is a cross-sectional illustration view of a portion of the composite IC device structure 100, showing components 106, 110, and 112, and TMVs 109, according to some embodiments. In some embodiments, components 106, 110, and 112 may be chiplets. As mentioned, components 106, 110, and 112 respectively include one or more BEOL metallization layers 134, 146, and 152 that have been monolithically fabricated over a device layer. FIG. 1B illustrates additional detail of BEOL metallization layers 134, 146, and 152. Specifically, metallization layers 134 include conductive layers 138 separated by inter-level dielectric (ILD) material layers 139. Metallization layers 146 include electrically conductive layers 156 separated by ILD material layers 158. Metallization layers 152 include electrically conductive layers 160 separated by ILD material layers 162. Substrate 132 may be homogenous with device layer 130, or not (e.g., a transferred substrate).

Device layers 130, 144, and 150 (and a homogeneous substrate 132) may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, the semiconductor material is a Group III-V material comprising a Group III majority constituent and a Group IV majority constituent (e.g., InGaAs, GaAs, GaSb, InGaSb). Device layers 130, 144, and 150 may have a thickness of 100-1000 nm, for example. Device layers 130, 144, and 150 need not be a continuous layer of semiconductor material, but rather may include active regions of semiconductor material surrounded by field regions of isolation dielectric. During front-end-of-line (FEOL) processing, active and/or passive devices are fabricated in chiplet device layers 130, 144, and 150 at some device density associated with device pitch Pi. In some embodiments, the active devices are field effect transistors (FETs) with a device pitch Pi of 80 nm, or less, for example. The FETs may be of any architecture (e.g., planar, non-planar, single-gate, multi-gate). In some embodiments, FET terminals have a feature pitch of 80-140 nm. In some embodiments, FET terminals have a feature pitch of 40-80 nm. Additionally, or in the alternative, chiplet device layers 130, 144, and 150 may include active devices other than FETs. For example, chiplet device layers 130, 144, and 150 may include electronic memory structures, such as magnetic tunnel junctions (MTJs), or the like. In addition to active devices, or instead of active devices, chiplet device layers 130, 144, and 150 may include passive devices (e.g., resistors, capacitors, inductors, etc.).

During back-end-of-line (BEOL) processing, active devices of chiplet device layers 130, 144, and 150 are interconnected into chiplet circuitry with one or more chiplet metallization layers 134. In some examples where device layers 130, 144, and 150 include both n-type and p-type FETs, the FETs are interconnected by respective metallization layers 134, 146, and 152 into a CMOS circuit. Metallization layers 134, 146 and 152 may comprise any number of respective conductive layers 138, 156, and 160 separated by respective ILD material layers 139, 158, and 162. Layer thicknesses for both conductive layers 138, 156, and 162 and dielectric material layers 139, 158, and 160 may range from 50 nm in the upper metallization layers near the interface with device layers 130, 144, and 150, to 5 μm, or more, in the lower metallization layers. Conductive layers 138, 156, and 160 may have any composition known to be suitable for monolithic integrated circuitry, such as, but not limited to, Cu, Ru, W, Ti, Ta, Co, their alloys, or nitrides. ILD material layers 139, 158, and 162 may be of any material composition known to be suitable as an insulator of monolithic integrated circuitry, such as, but not limited to, silicon dioxide, silicon nitride, silicon oxynitride, or a low-k material having a relative permittivity below 3.5. In some embodiments, ILD materials 139, 158, and 162 between metallization layers 138, 156, and 160 vary in composition with a lower ILD material layer comprising a low-k dielectric material and a lowest ILD material layer comprising a conventional dielectric material (e.g., having a dielectric constant of approximately 3.5, or more). Confining low-k dielectric materials from a bond interface in this manner may advantageously improve bond strength and/or quality. In other embodiments where low-k dielectric material is able to form a strong bond interface, all ILD material layers 140, 158, and 162 may be a low-k material (e.g., having a relative permittivity of 1.5-3.0).

In some embodiments, component 110 or component 112, or both components, are directly bonded to component 106 using a hybrid bonding process 155.

A highest one of metallization layers 140 of component 110 includes conductive or interconnect features 148. A highest one of metallization layers 152 of component 112 includes conductive or interconnect features 154. Conductive features 148 and 154 may be any composition and dimension suitable for directly bonding to conductive features of another component, e.g., interconnect features 136 of component 106. TMVs 109 may have any composition and dimension suitable for directly bonding to conductive features of another component, e.g., interconnect features 136 of component 106. In some embodiments, features 148 and 154, and TMVs 109, have a chemical composition and material microstructure of both high electrical conductivity and high thermal conductivity. As used herein, high thermal conductivity is on the order of 400 W/m·K. In some embodiments, features 148 and 154, as well as TMVs 109, are primarily copper (Cu). TMVs 109, and features 148 and 154 may, for example, be electroplated Cu and therefore have a microstructure with a very low void area percentage (e.g., less than 1%).

Metallization layers 134 include conductive interconnect features 136. In some embodiments, features 136 have a chemical composition and material microstructure of high electrical conductivity, but low thermal conductivity. The thermal conductivity of features 136 is significantly less than that of TMVs 109, or features 148 and 154. Features 136 are of dimensions suitable for directly bonding to conductive features of another component (e.g., features 148, features 154, or TMVs 109). In some embodiments, the thermal conductivity of features 136 is at least an order of magnitude less than that of interconnect features 148, 154, or TMVs 109. In some embodiments, the thermal conductivity of features 136 is at least 40 times lower than the thermal conductivity of features 148, 154, or TMVs 109. In advantageous embodiments, features 136 have a composition and microstructure of a thermal conductivity less than 400 W mK, and more advantageously on the order of 10 W/mK, or less. In some embodiments, the composition of features 136 is other than Cu. For other embodiments, features 136 are also primarily Cu, but the microstructure is of low density, for example having a void area percentage of at least 10%.

For embodiments where interconnect features 136 are a metal other than copper, features 136 may instead be primarily bismuth (Bi), tellurium (Te), manganese (Mn), indium (In), tin (Sn), zinc (Zn) or gallium (Ga), or an alloy of one or more of these metals.

In some embodiments, where interconnect features 148 and 154 are copper, interconnect features 136 comprise a metal other than copper and oxygen. For example, any of the metals listed above may be in a compound further including oxygen, such as, but not limited to InOₓ, SnOₓ, ZnOₓ or GaOₓ Alloyed metal oxides, such as InₓSn_{y}O_{z} (ITO) may also be particularly advantageous as good electrical conductors with high thermal resistance. Amounts of one or more metals and oxygen may be varied to achieve the greatest thermal resistance possible for the electrical conductivity required by the application.

In some alternative embodiments, interconnect features 136 comprise an electrically conductive polymer with one example being poly(3,4-ethylenedioxythiophene) polystyrene sulfonate (PEDOT:PSS).

Some bulk material properties of these exemplary materials are set forth in Table 1.

TABLE 1

| | | Specific Thermal |
|---|---|---|
| Material | Specific Resistivity | Conductivity |
| Low density Cu | 10⁻⁸ − 10⁻⁶ Ω · cm | 7-43 W/(m · K) |
| Bi | 13.4 × 10⁻⁶ Ω · cm | 8 W/(m · K) |
| PEDOT:PSS | 4.8 × 10⁻⁴ Ω · cm − | 0.3-2.2 W/(m · K) |
| | 4.8 × 10⁻⁶ Ω · cm | |
| Te | ~1 · 10⁻⁵ Ω · cm | 1.97-3.38 W/(m · K) |
| Mn | 1.44 μΩ · m | 7.81 W/(m · K) |
| In | 83.7 nΩ · m | 81.8 W/(m · K) |
| Sn | 115 nΩ · m | 66.8 W/(m · K) |
| Zn | 59.0 nΩ · m | 116 W/(m · K) |
| Ga | 270 nΩ · m | 40.6 W/(m · K) |
| ITO | ~10⁻⁴ Ω · cm | <4 W/(m · K) |
| IGZO | Btw. 10⁻³ Ω · cm − | <2 W/(m · K) |
| | 5 · 10⁻⁵ Ω · cm | |

When one of features 136 is in direct contact with one of features 148, 154, or TMV 109, as shown in FIG. 1A, the thermal resistance is improved at connection features while electrical conductivity is maintained. Thermally insulating one component from another in this manner may be advantageous, for example, where one component is heat sensitive and an adjacently stacked component generates heat. As one example, component 106 may be thermally sensitive and component 112 may generate substantially amounts of heat.

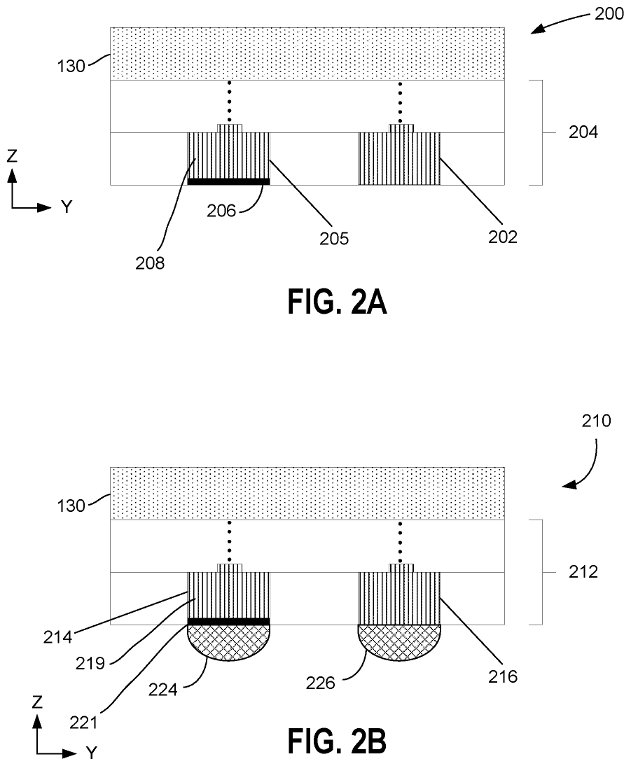

FIGS. 2A and 2B illustrate cross-sectional views of heat insulating electrical interconnect features of a portion of components 200 and 210 of a composite IC structure, in accordance with some embodiments. FIG. 2A illustrates component 200 having interconnect features, e.g., pads, 202 and 205. The portion of component 200 shown in FIG. 2A includes at least one device layer 130 and one or more BEOL metallization layers 204. In some embodiments, features 202 and 205 comprise a material that has low thermal conductivity, for example as described herein.

Referring to FIG. 2A, when component 200 is bonded to another component using hybrid bonding, dielectric material of metallization layers 204 form a chemical bond (such as a covalent bond) with dielectric material on the surface of the other component at room temperature (e.g. about 25 degrees Celsius). Subsequent to placing component 200 in contact with the other component, heat and/or pressure may be applied to interdiffuse metal across the bond interface.

In some embodiments, hybrid bond interconnect feature 205 comprises at least two portions, each having a distinct composition and/or microstructure. In some embodiments, a first portion 208 is of a composition or microstructure that has a low thermal conductivity, for example at least an order of magnitude lower, and advantageously at least 40 times lower than the thermal conductivity of non-porous copper. A second portion 206 is of composition or microstructure having high thermal conductivity, such as non-porous Cu or Ti. In some embodiments, the portion 206 has the same composition and/or microstructure as the feature to which interconnect feature 205 is bonded. For example, for embodiments where interconnect feature 205 is in contact with an interconnect feature comprising primarily non-porous copper, then portion 206 may also be non-porous copper. In some embodiments, the portion 206 has high thermal conductivity, for example substantially as described elsewhere herein

In some embodiments, first portion 208 is stacked with second portion 206. First portion 208 may advantageously have a larger volume than second portion 206. As illustrated, second portion 206 is advantageously located to directly contact a corresponding interconnect feature of another component. For example, second portion 206 is an outer surface of component 200. Portion 206 may therefore facilitate bonding while portion 208 increases thermal resistance of interconnect feature 205. In some embodiments, second portion 206 may be a thin layer at the surface of component 200. As one example, the interconnect feature 205 is 2 μm thick (z axis), and at least 1.9 μm of the thickness is first portion 208 with second portion 206 being only 0.1 μm of the total thickness.

FIG. 2B illustrates a portion of component 210 according to some other embodiments. Component 210 has interconnect features, e.g., pads, 214 and 216. The portion of component 210 shown in FIG. 2B includes at least one device layer 130. Component 210 includes one or more BEOL metallization layers 212. Component 210 is for use in interfaces other than a hybrid bond interface according to some embodiments.

Referring to FIG. 2B, in some embodiments, component 210 is to interface to another component through a solder feature. For example, interconnect features 214 and 216 may interface to an interconnect feature of another component through solder features 224 and 226. In some embodiments, interconnect feature 216 is primarily of a single homogeneous composition and microstructure. In some embodiments, interconnect feature 214 comprises at least two portions, each of a distinct material microstructure or chemical composition. In some embodiments, interconnect feature 216 and first portion 219 of feature 214 have a material microstructure or are of a chemical composition that has a low thermal conductivity, for example as described elsewhere herein. In some embodiments, a second interconnect feature portion 221 of feature 214 has a material microstructure or chemical composition suitable as a surface finish that can form an intermetallic bond with solder feature 224. For example, second portion 221 may comprise Cu or Ni. First portion 219 is similarly stacked with second portion 221. First portion 219 may again be larger in volume than second portion 221.

In some embodiments, a through-via comprises electrically conductive material of high thermal resistance/low thermal conductivity. Such thermally resistive through vias may be through-glass vias (TGV), through-semiconductor vias (TSVs), or through mold vias (TMVs). In some embodiments, a through-via is of low thermal conductivity, for example substantially as described elsewhere herein.

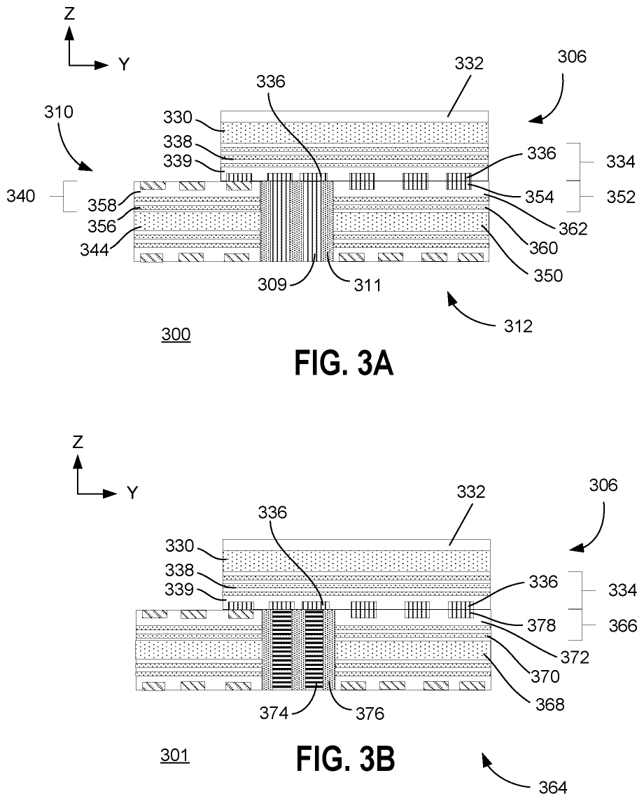

FIGS. 3A and 3B illustrate cross-sectional views of portions 300 and 301 of composite IC device structures, in accordance with some embodiments. In FIG. 3A, example portion 300 includes components 306, 310, and 312, and TMVs 309, according to some embodiments. Components 306, 310, and 312 respectively include one or more BEOL metallization layers 334, 340, and 352 that have been monolithically fabricated over respective device layers 330, 344, and 350. Metallization layers 334 include conductive layers 338 separated by ILD material layers 339. Metallization layers 340 include conductive layers 356 separated by ILD material layers 358. Metallization layers 352 include conductive layers 360 separated by ILD material layers 362.

In some embodiments, a highest one of metallization layers 352 of component 312 includes conductive interconnect features 354. In some embodiments, conductive features 354 are of low thermal conductivity, for example substantially as described elsewhere herein. In example portion 300, respective interconnect features 336 are in direct contact with interconnect features 354, and both interconnect features 336 and 354 are of low thermal conductivity, for example substantially as described elsewhere herein. This double thickness of thermal resistive material may further reduce thermal conduction between components 306 and 312.

In example portion 300, respective interconnect features 336 are in direct contact with TMVs 309. TMVs 309 are of low thermal conductivity, for example substantially as described elsewhere herein. The increased thickness of thermal resistive material provided by TMVs 309 may further reduce thermal conduction between component 306 and a component not depicted in FIG. 3A that has interconnect features in contact with the lower ends of TMVs 309.

In FIG. 3B, example portion 300 includes component 306 stacked with component 364, according to some embodiments. Component 364 includes one or more BEOL metallization layers 366 that have been monolithically fabricated over device layer 368. Metallization layers 366 include conductive layers 370 separated by ILD material layers 372. Component 364 may include one or more features 374 encapsulated by composition 376. In some embodiments, features 374 are TGVs and composition 376 is any suitable glass material. In some embodiments, features 374 are TSVs and composition 376 is any suitable substrate material.

In both example portions 300 and 301, a lowest one of metallization layer 334 of component 306 includes electrically conductive interconnect features 336. In some embodiments, features 336 are of low thermal conductivity, for example substantially as described elsewhere herein. In example portion 301, respective interconnect features 336 are in direct contact with TGV/TSV 374 and interconnect features 378, and all of interconnect features 336, interconnect features 378, and TGV/TSV 374 are of low thermal conductivity, for example substantially as described elsewhere herein.

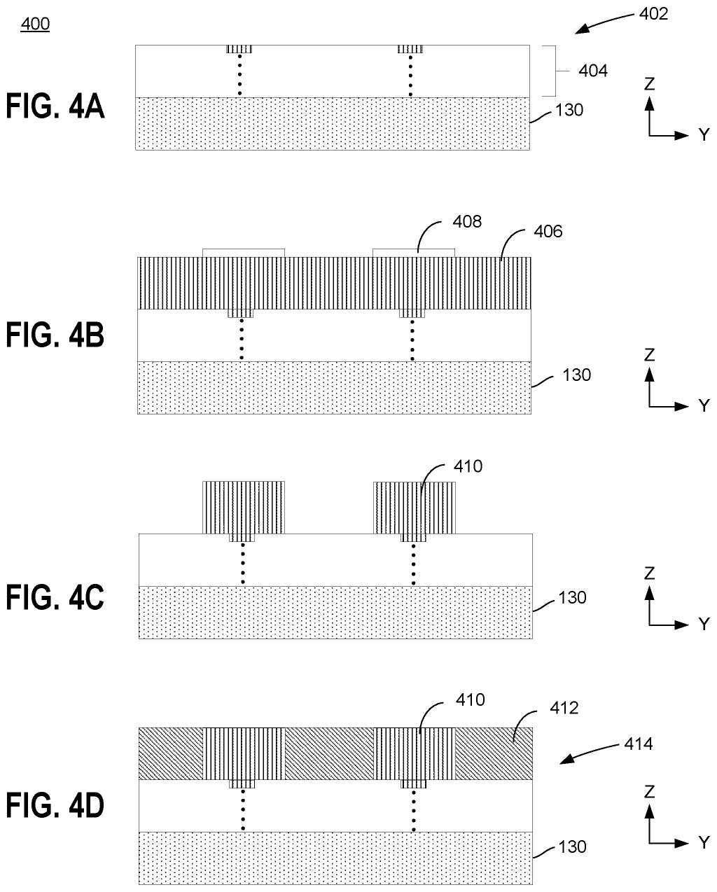

The thermally resistive electrically conductive interconnect features described herein may be fabricated according to any known techniques, such as any subtractive of semi-additive techniques. FIGS. 4A, 4B, 4C, and 4D, illustrate cross-sectional views of thermally insulating interconnect features of a component of a composite IC device structure evolving during a fabrication process, in accordance with some subtractive embodiments. FIG. 4A illustrates a component 402 that may be received as a starting material or fabricated in a monolithic IC process. The component 402 includes a device layer 130 and a metallization layer 404. The device layer 130 may be between a substrate (not shown in FIG. 4A-D) and the metallization layer 404. The component 402 lacks one or more interconnect features on at least one surface. FIG. 4B illustrates a layer 406 of a material or composition deposited or plated on the upper surface of metallization layer 404. In some embodiments, layer 406 is of low thermal conductivity, for example substantially as described elsewhere herein. Layer 406 may be applied using any standard BEOL process. Etch masks 408 may be formed on layer 406. As shown in FIG. 4C, recesses may be formed during an etch process in areas defined by etch masks 408. Any standard BEOL process for removing material may be employed, resulting in interconnect features 410. As illustrated in FIG. 4D, dielectric material 412 is deposited in the recesses surrounding interconnect features 410. The process of surrounding interconnect features 410 with dielectric material 412 may include depositing dielectric material over the entire upper surface of the component and then removing excess material from the surface. This phase of the process may include planarizing the surface of the component using any standard BEOL process, e.g., CMP. Planarization may expose interconnect features 410. Prior to bonding with another component, component 414 may be pre-processed, e.g., with a plasma clean, to activate the upper surface for bonding.

While not shown in FIG. 4A-D, in some embodiments, any surface finish suitable for direct bonding or subsequent solder application may be further plated or otherwise deposited using any known techniques on interconnect features 410. In some embodiment, the surface finish is of composition or microstructure having high thermal conductivity, for example substantially as described elsewhere herein. In some embodiments, the surface finish has the same composition and/or microstructure as a feature it directly contacts when component 402 is assembled into a composite IC device structure.

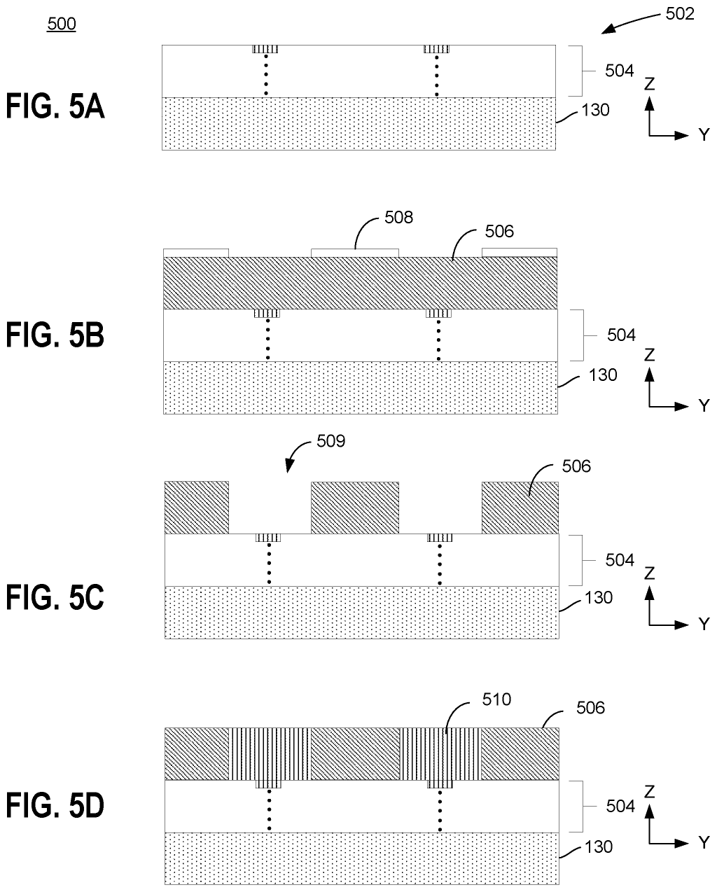

FIGS. 5A, 5B, 5C, 5D, and 5E illustrate cross-sectional views of heat insulating interconnect features of a component of a composite IC device structure evolving during a fabrication process, in accordance with some alternative semi-additive processing embodiments. FIG. 5A illustrates a component 502 that may be received as a starting material or fabricated in a monolithic IC process. The component 502 includes a device layer 130 and a metallization layer 504. The device layer 130 may be between a substrate (not shown in FIG. 5A-E) and the metallization layer 504. The component 502 lacks one or more interconnect features on at least one surface.

FIG. 5B illustrates a dielectric layer 506 of a material or composition deposited or laminated on the upper surface of metallization layer 504. Etch masks 508 may be formed on layer 506, and openings 509 formed in dielectric layer 506 according the mask 508, as shown in FIG. 5C. As illustrated in FIG. 5D, an electrically conductive material or composition 510 may be deposited or plated into the openings 509 in dielectric layer 506. In some embodiments, electrically conductive material 510 is of low thermal conductivity, for example substantially as described elsewhere herein. As shown in FIG. 5E, any surface finish 512 suitable for direct bonding or subsequent solder application may be further plated or otherwise deposited using any known techniques. In some embodiment, surface finish 512 is of composition or microstructure having high thermal conductivity, for example substantially as described elsewhere herein. In some embodiments, surface finish 512 has the same composition and/or microstructure as a feature it directly contacts when component 502 is assembled into a composite IC device structure.

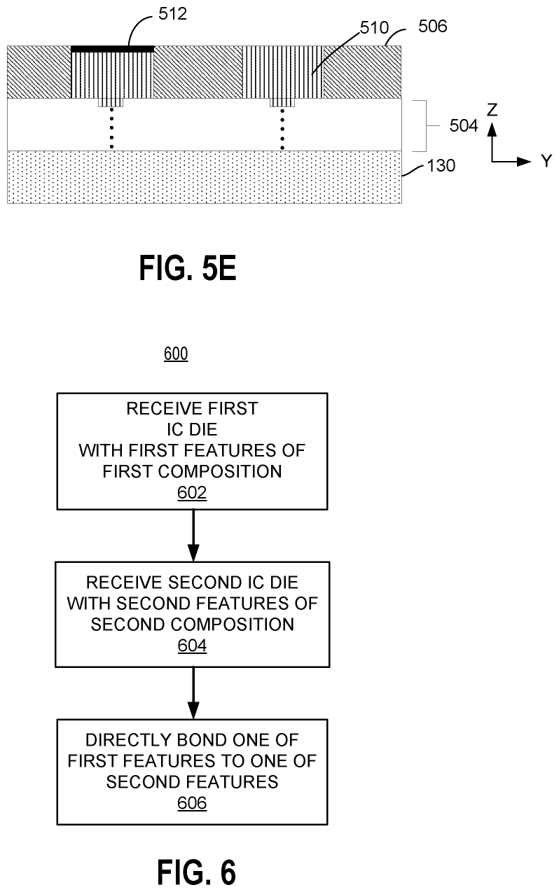

FIG. 6 is flow diagram of a method 600 for assembling a composite IC structure having a component that includes at least one heat insulating interconnect feature, in accordance with some embodiments. In operation 602, a first IC die or component is received. The received first IC die includes a first device layer and one or more first metallization layers interconnected to transistors of the first device layer and terminating at first features. The first features are primarily of a first composition. The first features have a chemical composition and material microstructure of both high electrical conductivity and high thermal conductivity. In some embodiments, the first features have a high thermal conductivity, as defined herein. In some embodiments, are primarily copper. In some embodiments, the first features have a microstructure with a very low void area percentage (e.g., less than 1%).

In operation 604, a second IC die in a stack with the first IC die is received. The second IC die includes a second device layer and one or more second metallization layers interconnected to transistors of the second device layer and terminating at second features. The second features have a chemical composition and material microstructure of high electrical conductivity, but low thermal conductivity. The thermal conductivity of the second features is significantly less than that of the first features. In some embodiments, the thermal conductivity of the second features is at least an order of magnitude less than that of the second features. In some embodiments, the thermal conductivity of the second features is at least 40 times lower than the thermal conductivity of the first features. In advantageous embodiments, the second features have a composition and microstructure of a thermal conductivity less than 400 W mK, and more advantageously on the order of 10 W/m·K, or less. In some embodiments, the composition of the second features is other than Cu. For other embodiments, the second features are also primarily Cu, but the microstructure is of low density, for example having a void area percentage of at least 10%

In operation 606, one or more of the first features are directly bonded to corresponding ones of the second features.

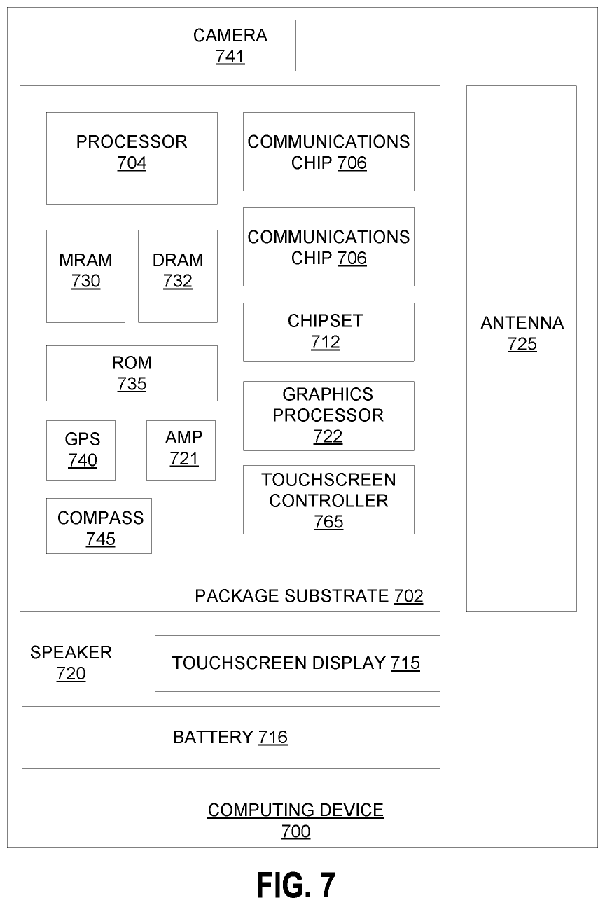

FIG. 7 is a functional block diagram of an electronic computing device 700, in accordance with an embodiment. Device 700 further includes a package substrate 702 hosting a number of components, such as, but not limited to, a processor 704 (e.g., an applications processor). Processor 704 may be physically and/or electrically coupled to package substrate 702. In some examples, processor 704 is within a composite IC chip structure including a chiplet bonded to a host IC chip, for example as described elsewhere herein. Processor 704 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to the package substrate 702. In further implementations, communication chips 706 may be part of processor 704. Depending on its applications, computing device 700 may include other components that may or may not be physically and electrically coupled to package substrate 702. These other components include, but are not limited to, volatile memory (e.g., DRAM 732), non-volatile memory (e.g., ROM 735), flash memory (e.g., NAND or NOR), magnetic memory (MRAM 730), a graphics processor 722, a digital signal processor, a crypto processor, a chipset 712, an antenna 725, touchscreen display 715, touchscreen controller 765, battery 716, audio codec, video codec, power amplifier 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth), or the like. In some exemplary embodiments, at two of the functional blocks noted above are within a composite IC chip structure including a chiplet bonded to a host IC chip, for example as described elsewhere herein. For example, processor 704 be implemented with circuitry in a first of the host IC chip and chiplet, and an electronic memory (e.g., MRAM 730 or DRAM 732) may be implemented with circuitry in a second of the host IC chip and chiplet.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 706 may implement any of a number of wireless standards or protocols. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

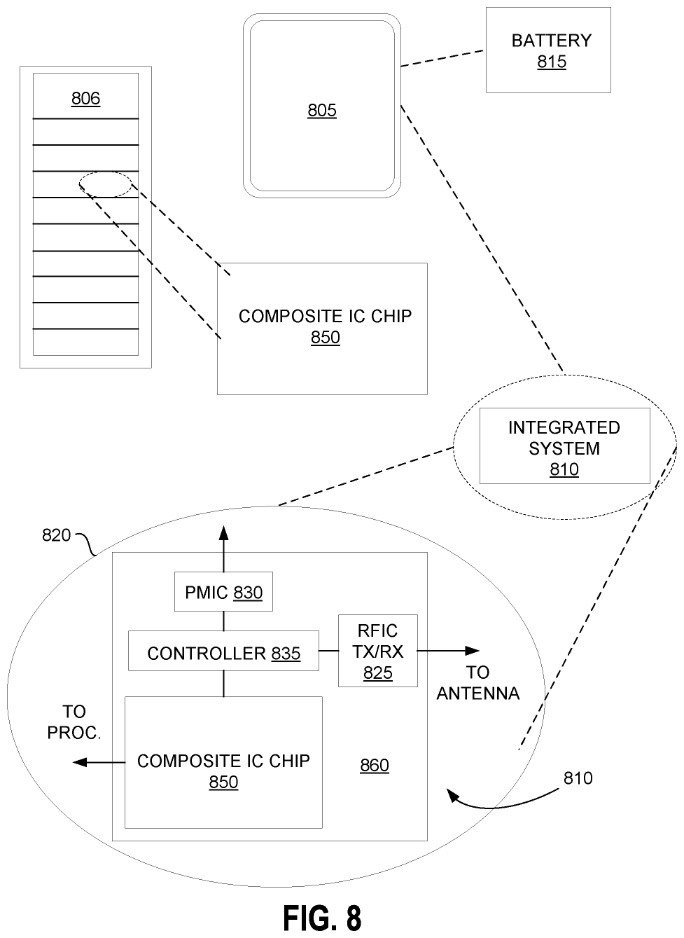

FIG. 8 illustrates a mobile computing platform and a data server machine employing a composite IC chip structure, for example as described elsewhere herein. Computing device 700 may be found inside platform 805 or server machine 806, for example. The server machine 806 may be any commercial server, for example including any number of high-performance computing platforms disposed within a rack and networked together for electronic data processing, which in the exemplary embodiment includes a composite IC chip 850 that includes a chiplet bonded to a host IC chip, for example as described elsewhere herein. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), a chip-level or package-level integrated system 810, and a battery 815.

Whether disposed within the integrated system 810 illustrated in the expanded view 820, or as a stand-alone package within the server machine 806, composite IC chip 850 may include a chiplet bonded to a host IC chip, for example as described elsewhere herein. Composite IC chip 850 may be further coupled to a host substrate 860, along with, one or more of a power management integrated circuit (PMIC) 830, RF (wireless) integrated circuit (RFIC) 825 including a wideband RF (wireless) transmitter and/or receiver (TX/RX) (e.g., including a digital baseband and an analog front end module further comprises a power amplifier on a transmit path and a low noise amplifier on a receive path), and a controller 835. PMIC 830 may perform battery power regulation, DC-to-DC conversion, etc., and so has an input coupled to battery 815 and with an output providing a current supply to other functional modules. As further illustrated, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

In first examples, a microelectronic device structure comprises a first integrated circuit (IC) die comprising a first device layer and one or more first metallization layers interconnected to transistors of the first device layer and terminating at first features. The first features are primarily of a first composition with a first microstructure. The microelectronic device structure comprises a second IC die in a stack with the first IC die, the second IC die comprising a second device layer and one or more second metallization layers interconnected to transistors of the second device layer and terminating at second features. The second features are primarily of a second composition or a second microstructure having a thermal conductivity at least an order of magnitude lower than that of the first composition and first microstructure. A first one of the second features is in direct contact with one of the first features.

In second examples, for any of the first examples, the first composition with the first microstructure has a thermal conductivity at least 40 times that of the second composition or second microstructure.

In third examples, for any of the first or second examples, the second microstructure is more porous than the first microstructure.

In fourth examples, for any of the first through third examples, the first and second compositions are both primarily the same metal.

In fifth examples, for any of the first through fourth examples, the first composition comprises Cu. The second composition comprises a metal other than Cu, or a polymer.

In sixth examples, for any of the first through the fifth examples, the metal is Bi, Te, or Mn.

In seventh examples, for any of the sixth examples, the second composition comprises the metal and oxygen.

In eighth examples, for any of the seventh examples, the metal is In, Sn, Zn or Ga.

In ninth examples, for any of the first through the eighth examples, the second features further comprise a surface finish in direct contact with the first interconnect features. The surface finish has a composition different than the second composition.

In tenth examples, for any of the ninth examples, the surface finish comprises Cu or Ni.

In eleventh examples, for any of the first through the tenth examples, the device structure comprises a third IC die in a stack with the first IC die and adjacent to the second IC die. The third IC die comprises a third device layer and one or more third metallization layers interconnected to transistors of the third device layer and terminating at third features. The third features are primarily of the first composition. A second one of the third features is in direct contact with one of the first features.

In twelfth examples, for any of the first through the tenth examples, the device structure comprises a third IC die in a stack with the first IC die and adjacent to the second IC die. The third IC die comprises a third device layer and one or more third metallization layers interconnected to transistors of the third device layer and terminating at third features. The third features are primarily of the second composition. One of the third features is in direct contact with one of the second features.

In thirteenth examples, a microelectronic device structure comprises a first integrated circuit (IC) die comprising a first device layer and one or more first metallization layers interconnected to transistors of the first device layer and terminating at first features. The device structure comprises a second IC die in a stack with the first die, the second IC die comprising a second device layer and one or more second metallization layers interconnected to transistors of the second device layer and terminating at second features. The second features have a second void area percentage of at least 10%, and greater than that of the first features. One of the second features is interconnected to one of the first features.

In fourteenth examples, for any of the thirteenth examples, the first and second features both comprise Cu and the first feature has a void area percentage of less than 1%.

In fifteenth examples, for any of the thirteenth or fourteenth examples, the first features are in direct physical contact with the second features.

In sixteenth examples, for any of the thirteenth through fifteenth examples, the first features are coupled to the second features through an intervening solder interconnect feature.

In seventeenth examples, for any of the thirteenth through fifteenth examples, the first IC die and the second IC die are directly bonded using a hybrid bonding process.

In eighteenth examples, a system comprises the integrated circuit (IC) device of the first example and a power supply coupled to provide power to the IC device.

In nineteenth examples, for any of the eighteenth examples, the first IC chip comprises memory circuitry to store data, and the second IC chip comprises logic circuitry to execute instructions on the data.

In twentieth examples, a method of assembling an integrated circuit (IC) device comprises receiving a first IC die comprising a first device layer and one or more first metallization layers interconnected to transistors of the first device layer and terminating at first features. The first features are primarily of a first composition with a first microstructure. The method comprises receiving a second IC die in a stack with the first IC die. The second IC die comprises a second device layer and one or more second metallization layers interconnected to transistors of the second device layer and terminating at second features. The second features are primarily of a second composition or a second microstructure having a thermal conductivity at least an order of magnitude lower than that of the first composition and first microstructure. The method comprises directly bonding ones of the first features to ones of the second features.

In twenty-first examples, for any of the twentieth examples, the first composition with the first microstructure has a thermal conductivity at least 40 times that of the second composition or second microstructure.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. A microelectronic device structure, comprising:
a first integrated circuit (IC) die comprising a first device layer and one or more first metallization layers interconnected to transistors of the first device layer and terminating at first features, wherein the first features are primarily of a first composition with a first microstructure;
a second IC die in a stack with the first IC die, the second IC die comprising a second device layer and one or more second metallization layers interconnected to transistors of the second device layer and terminating at second features, wherein:
the second features are primarily of a second composition or a second microstructure having a thermal conductivity at least an order of magnitude lower than that of the first composition and first microstructure; and
a first one of the second features is in direct contact with one of the first features.

2. The device structure of claim 1, wherein the first composition with the first microstructure has a thermal conductivity at least 40 times that of the second composition or second microstructure.

3. The device structure of claim 1, wherein the second microstructure is more porous than the first microstructure.

4. The device structure of claim 3, wherein the first and second compositions are both primarily the same metal.

5. The device structure of claim 1, wherein: the first composition comprises Cu; and the second composition comprises a metal other than Cu, or a polymer.

6. The device structure of claim 5, wherein the metal is Bi, Te, or Mn.

7. The device structure of claim 5, wherein the second composition comprises the metal and oxygen.

8. The device structure of claim 7, wherein the metal is In, Sn, Zn or Ga.

9. The device structure of claim 1, wherein the second features further comprise a surface finish in direct contact with the first interconnect features, the surface finish having a composition different than the second composition.

10. The device structure of claim 9, wherein the surface finish comprises Cu or Ni.

11. The device structure of claim 1, further comprising a third IC die in a stack with the first IC die and adjacent to the second IC die, the third IC die comprising a third device layer and one or more third metallization layers interconnected to transistors of the third device layer and terminating at third features, wherein:
the third features are primarily of the first composition; and
a second one of the third features is in direct contact with one of the first features.

12. The device structure of claim 1, further comprising a third IC die in a stack with the first IC die and adjacent to the second IC die, the third IC die comprising a third device layer and one or more third metallization layers interconnected to transistors of the third device layer and terminating at third features, wherein:
the third features are primarily of the second composition; and
one of the third features is in direct contact with one of the second features.

13. A microelectronic device structure, comprising:
a first integrated circuit (IC) die comprising a first device layer and one or more first metallization layers interconnected to transistors of the first device layer and terminating at first features;
a second IC die in a stack with the first die, the second IC die comprising a second device layer and one or more second metallization layers interconnected to transistors of the second device layer and terminating at second features, wherein:
the second features have a second void area percentage of at least 10%, and greater than that of the first features; and
one of the second features is interconnected to one of the first features.

14. The device structure of claim 13, wherein the first and second features both comprise Cu and the first feature has a void area percentage of less than 1%.

15. The device structure of claim 13, wherein the first features are in direct physical contact with the second features.

16. The device structure of claim 13, wherein the first features are coupled to the second features through an intervening solder interconnect feature.

17. The device structure of claim 13, wherein the first IC die and the second IC die are directly bonded using a hybrid bonding process.

18. A system comprising:
the integrated circuit (IC) device of claim 1; and
a power supply coupled to provide power to the IC device.

19. The system of claim 18, wherein:
the first IC chip comprises memory circuitry to store data; and
the second IC chip comprises logic circuitry to execute instructions on the data.

20. A method of assembling an integrated circuit (IC) device;
receiving a first IC die comprising a first device layer and one or more first metallization layers interconnected to transistors of the first device layer and terminating at first features, wherein the first features are primarily of a first composition with a first microstructure;
receiving a second IC die in a stack with the first IC die, the second IC die comprising a second device layer and one or more second metallization layers interconnected to transistors of the second device layer and terminating at second features, wherein:
the second features are primarily of a second composition or a second microstructure having a thermal conductivity at least an order of magnitude lower than that of the first composition and first microstructure; and
directly bonding ones of the first features to ones of the second features.

21. The method of claim 20, wherein the first composition with the first microstructure has a thermal conductivity at least 40 times that of the second composition or second microstructure.
